(19) United States
(12) Patent Application Publication
(10) Pub. No.: US 2005/0242360 A1
(43) Pub. Date: Nov. 3, 2005

(54) White light apparatus with adjustable color temperature and method of producing white light thereof

(76) Inventor: Hung-Yuan Su, Taipei City (TW)

Correspondence Address: RABIN & BERDO, P.C., Suite 500, 1101 14th Street, N.W., Washington, DC, 20005, US

(21) Appl. No.: 11/060,396

(22) Filed: Feb. 18, 2005

(30) Foreign Application Priority Data
Apr. 29, 2004 (TW) 93111938

(51) Int. Cl. H01L 29/20

(52) U.S. Cl. 257/99

(57) ABSTRACT

A white light apparatus with adjustable color temperature and a method of producing a white light thereof are disclosed. The white light apparatus includes a blue light-emitting diode, a phosphor powder and an orange light-emitting diode or a blue-green light-emitting diode. Furthermore, the method includes the following steps. Firstly, the blue light-emitting diode is provided for emitting a blue light. Secondly, the phosphor powder is prepared for emitting a phosphor light mixed with the blue light to produce the white light. Finally, the orange light-emitting diode or the blue-green light-emitting diode is controlled by a driving current, thereby to adjust the color temperature of the white light of the white light apparatus.

### BACKGROUND OF THE INVENTION

1. Field of the Invention

The preferred embodiment of the present invention relates to a white light apparatus with adjustable color temperature and method of producing white light thereof, and particularly to a method of utilizing one luminescent component which is controlled by varying driving current for decreasing or increasing color temperature value of the white light from the white light apparatus.

2. Description of Prior Art

A white light source is generally provided via mixing light source of different wavelength, and white light sensed by human vision is generally composed of light of at least two colors. For instance, a conventional white light source can be realized by mixing red light, green light and blue light with suitable intensity ratio. Alternatively, the white light source can be realized by mixing yellow light and blue light with suitable intensity ratio. Nowadays, most white light apparatus include fluorescent lamps, incandescent lamps, and white light-emitting diodes (white LED) that are currently under development. The color temperature of white light provided by a fluorescent lamp is about 7500 K, and the color temperature of white light provided by an incandescent lamp is about 3000 K.

Conventionally, there are many methods of obtaining a white light apparatus. The first conventional method is to use three light-emitting diodes (LEDs) to provide red, green and blue light by controlling a corresponding driving current respective to each LED. One of the three LEDs is made of InGaAlP, and the other two are made of GaN. The red, green and blue light emitted from the three LEDs are mixed together, thereby to produce white light.

The second conventional method is similar to the first conventional methods; the difference therebetween is that the second methods uses only two LEDs made of GaN and InGaAlP to provide blue light and yellow-green light or green light and red light for producing white light.

The third conventional method was developed by Japan Nichia Chemical Industries, Ltd., in 1996 and provides a white light apparatus using a blue light-emitting diode of an InGaN semiconductor combined with a yttrium aluminum garnet (“YAG:Ce”) phosphor material, which emits yellow light. The mixture of these blue and yellow emitted lights can also be perceived as white light by an observer.

The fourth conventional method was developed by Sumitomo Electric in 1999, and provides a white LED made of a ZnSe material. This method firstly forms a CdZnSe film on a ZnSe single crystal base. The CdZnSe film emits a blue light with a driving current, and the base is excited by a part of the blue light and then emits a yellow light. The blue light and the yellow light are mixed together for producing white light.

The fifth method uses an ultraviolet LED to excite much phosphor powder to emit lights with multiple colors, and mixture of these multiple colors of emitted light are perceived as white light by an observer.

However, the conventional methods as described above suffer from the following disadvantages. Except the first and second conventional methods, the other conventional methods can only provide a white light with a single constant color temperature; i.e., the color temperature thereof cannot be adjusted. On the other hand, although the first conventional method can generate the white light of different color temperature by modulating the corresponding driving current respective to each LED, it is expensive and complicated since each LED needs an independent controlling circuit. Similar to the first conventional method, the second conventional method can also generate the white light in different color temperature values by modulating the corresponding driving current respective to each LED. However, only two kinds of lights are available for producing white light in this method, so that color temperature of the white light is adjustable in a limited range, and is unable to attain color temperatures of some common light sources, such as 7500 K of a fluorescent lamp or 3000 K of an incandescent lamp.

FIG. 1 shows an emission spectrum according to a conventional blue light-emitting diode. As shown in FIG. 1, the blue light-emitting diode has a wavelength ranging from 430 nm to 530 nm.

FIG. 2 shows an emission spectrum according to a conventional orange light-emitting diode. As shown in FIG. 2, the orange light-emitting diode has a wavelength ranging from 530 nm to 630 nm.

Therefore, the preferred embodiment of the present invention provides an improved white light luminescence method and a luminescent device for the same that can overcome or at least reduce the disadvantages set forth above.

### SUMMARY OF THE INVENTION

In accordance with one aspect of the present invention, a method of producing a white light with adjustable color temperature includes: providing a blue light-emitting diode emitting a blue light which has a wavelength in a range from 400 nm to 500 nm; preparing a phosphor powder emitting a phosphor light which has a wavelength in a range from 540 nm to 700 nm, wherein the phosphor light is mixed with the blue light of the blue light-emitting diode to produce a white light with a color temperature value above 6500 K; and adding an orange light-emitting diode emitting a light which has a wavelength in a range from 540 nm to 600 nm, wherein the orange light-emitting diode can be controlled by a driving current for adjusting the color temperature of the white light.

In accordance with another aspect of the present invention, a white light apparatus with adjustable color temperature includes: a blue light-emitting diode emitting a blue light; a phosphor powder emitting a phosphor light, wherein the phosphor light is mixed with the blue light of the blue light-emitting diode to produce a white light with a high or a low color temperature value; and a luminescent component emitting a light which has a wavelength in a range from 480 nm to 600 nm, wherein the luminescent component can be controlled by a driving current for adjusting the color temperature of the white light.

### BRIEF DESCRIPTION OF THE DRAWINGS

Other objectives, advantages, and novel features of the present invention will become more apparent from the following detailed description when taken in conjunction with the accompanying drawings, in which:

FIG. 1 shows an emission spectrum according to a conventional blue light-emitting diode;

FIG. 2 shows an emission spectrum according to a conventional orange light-emitting diode;

FIG. 3 shows a schematic diagram of a white light apparatus according to the preferred embodiment of the present invention;

FIG. 4 is a chromaticity diagram showing the color coordinate points of the luminescent components in accordance with the preferred embodiment of the present invention;

FIG. 5 shows an emission spectrum of a white light with a high color temperature value in accordance with the preferred embodiment of the present invention; and

FIG. 6 shows an emission spectrum of a white light with a low color temperature value in accordance with the preferred embodiment of the present invention.

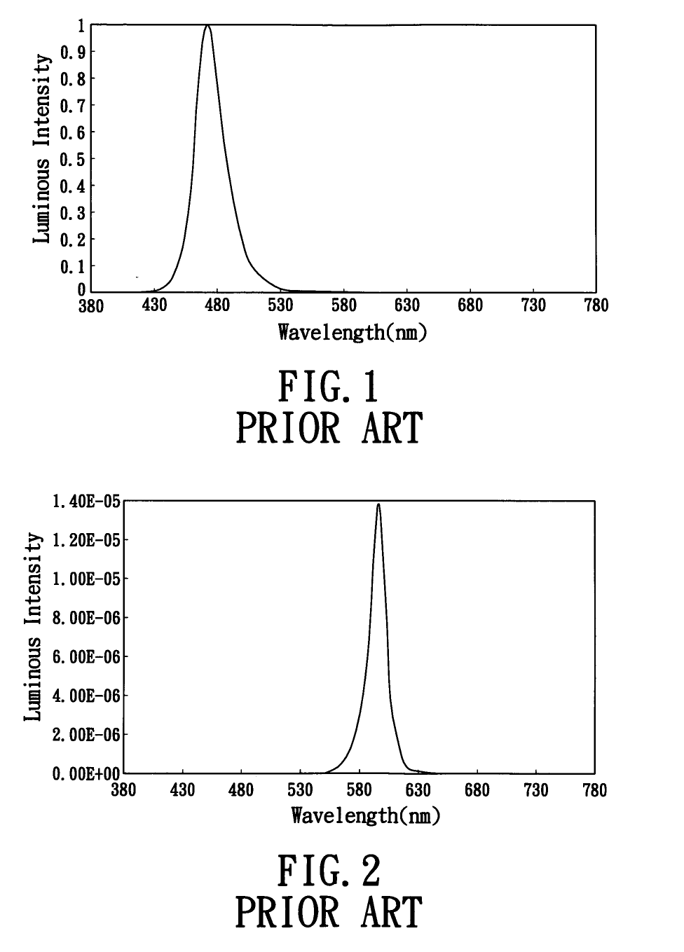

### DETAILED DESCRIPTION OF PREFERRED EMBODIMENTS

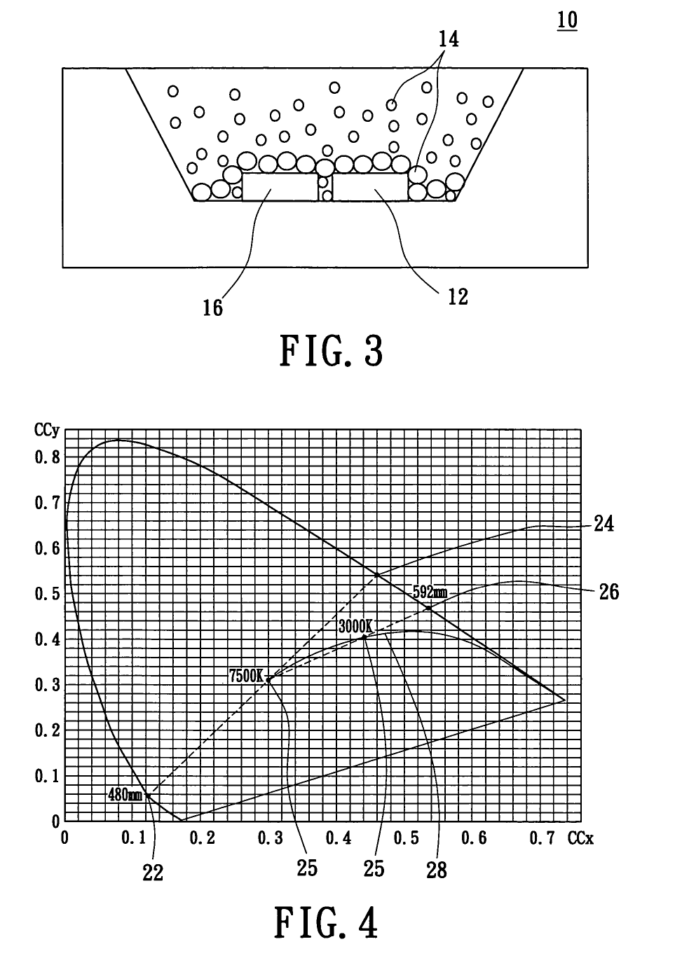

The preferred embodiment of the present invention is intended to a white light apparatus with adjustable color temperature and a method of producing a white light thereof. FIG. 3 shows a schematic diagram of a white light apparatus 10 including a first luminescent component 12, a second luminescent component 14 and a third luminescent component 16. The first luminescent component 12 is a blue light-emitting diode having a luminescent layer that is made of a nitride semiconductor or a phosphide semiconductor. The blue light-emitting diode is applied via a fixed driving current, for instance 30 mA, so as to emit a blue light 22 with reference to 480 nm (shown in FIG. 4). The blue light 22 has a wavelength in a range from 400 nm to 500 nm.

The second luminescent component 14 is a phosphor powder, preferable to a phosphor powder emitting a yellow light. The phosphor powder can emit a phosphor light 24 (shown in FIG. 4) when the phosphor powder is excited by the blue light emitted from the first luminescent component 12. The phosphor light 24 has a wavelength in a range from 540 nm to 700 nm. The phosphor powder is one of A₃B₅O₁₂:Ce, Gd, CaS:Eu and SrGa₂S₄:Eu, wherein the A element of the A₃B₅O₁₂:Ce phosphor powder is selected from a group consisting of Y, Tb, La, Gd, Pr and Sm, and the B element of the A₃B₅O₁₂:Ce phosphor powder is selected from a group consisting of Al, Ga, In and Fe for being activated with Ce. Further, the phosphor light 24 can be mixed with the blue light of the blue light-emitting diode to produce a white light 25 with a high or a low color temperature value (i.e. above 6500 K or below 6500 K).

The third luminescent component 16 is an orange light-emitting diode having a luminescent layer that is made of a nitride semiconductor or a phosphide semiconductor. The orange light-emitting diode is controlled due to an adjustable driving current, to emit an orange light 26 with reference to 592 nm (shown in FIG. 4). The orange light 26 has a wavelength in a range from 540 nm to 600 nm. Alternatively, The third luminescent component 16 can also be a blue-green light-emitting diode emitting a light having a wavelength in a range from 480 nm to 500 nm. Furthermore, the third luminescent component 16 can be adjusted by the driving current for decreasing or increasing the color temperature value of the white light of the white light apparatus 10. The color temperature value of the white light of the white light apparatus 10 can be adjusted in a range from 2000 K to 20000 K.

FIG. 4 is a chromaticity diagram showing the color coordinate points of the luminescent components in accordance with the preferred embodiment of the present invention. The blue light-emitting diode is used as a main luminescent component. The blue light 22 of the blue light-emitting diode is absorbed by the phosphor powder, thereby to produce the white light 25 with the color temperature value about 7500 K. Next, the orange light 26 of the orange light-emitting diode can be mixed with the white light 25. As shown in FIG. 4, when applying different driving current values to the third luminescent component 16 (such as the orange light-emitting diode), the color temperature value of the white light 25 is gradually decreased to about 3000 K along black body locus (BBL) 28 in the chromaticity diagram. This black body locus 28 is a theoretical connecting line according to a color light mixing principle.

Next, the white light apparatus 10 is provided for producing the white light with adjustable color temperature, as following steps. Firstly, the blue light-emitting diode is provided for emitting the blue light. Secondly, the phosphor powder is prepared for emitting a phosphor light mixed with the blue light of the blue of light-emitting diode to produce the white light with a high or a low color temperature value (i.e. above or below 6500 K). Sequentially, the orange light-emitting diode or blue-green light-emitting diode of the third luminescent component 16 can be adjusted by varying the driving current inputted into the third luminescent component 16, thereby to decrease or increase the color temperature value of the white light of the white light apparatus 10.

Preferably, the phosphor powder is selected from a group consisting of Y₃Al₅O₁₂:Ce, Gd, CaS:Eu and SrGa₂S₄:Eu. The phosphor powder is prepared by one of a solid reaction method and a chemical synthesizing method. The chemical synthesizing method is a citrate gel method or a co-precipitation method.

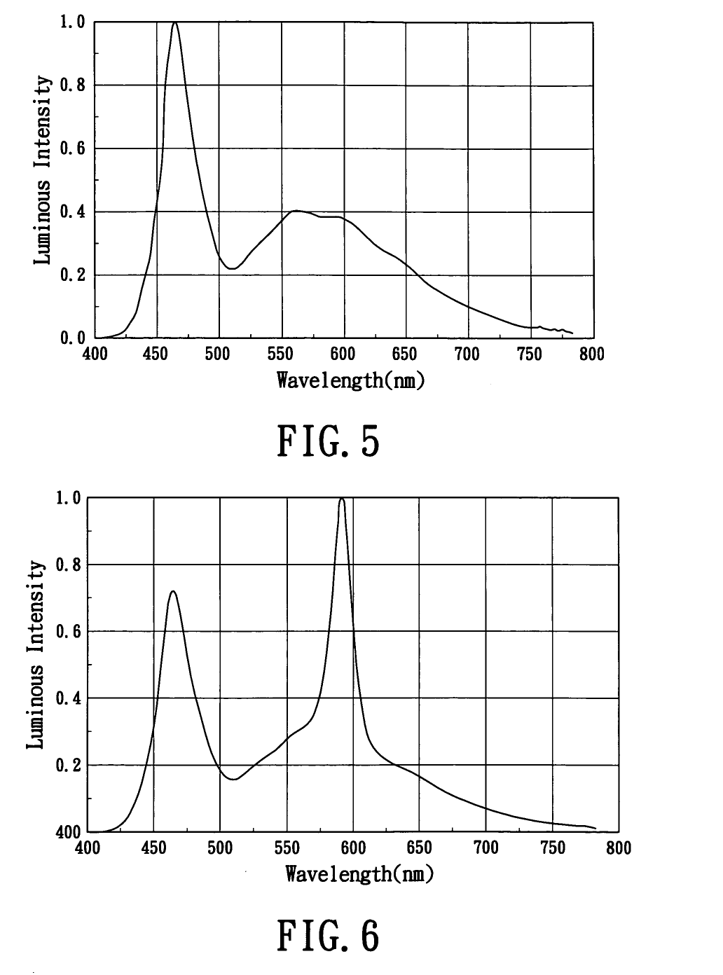

FIG. 5 shows an emission spectrum of a white light with a high color temperature value in accordance with the preferred embodiment of the present invention. That is, the white light 25 with the high color temperature value (7500 K) is produced when the phosphor powder is prepared for emitting a phosphor light mixed with the blue light of the blue light-emitting diode.

FIG. 6 shows an emission spectrum of a white light with a low color temperature value in accordance with the preferred embodiment of the present invention. That is, the white light 25 with the low color temperature value (3000 K) is produced when the phosphor powder is prepared for emitting a phosphor light with the blue light of the blue light-emitting diode and then adding the orange light of the orange light-emitting diode.

To sum up, the white light apparatus provided by the preferred embodiment of the present invention has peculiar advantages over prior art white light apparatus in following aspects:

1. In the preferred embodiment of the present invention, the color temperature value of the white light emitted from the white light apparatus can be adjusted by varying a driving current value of applying to the third luminescent component 16.

For example, the color temperature value of the white light of the white light apparatus can be adjusted in either 7500 K of the phosphor lamp or 3000 K of the incandescent lamp.

2. In the preferred embodiment of the present invention, only one chip is required for controlling the driving current to the third luminescent component 16, so that driving circuit of the preferred embodiment of the present invention can be simple and cheaper.

3. In the preferred embodiment of the present invention, the phosphor powder is of crystal structure, thereby to improve uniformity of the white light of the white light apparatus.

There has thus been described a new, novel and heretofore unobvious white light apparatus with adjustable color temperature which eliminates the aforesaid problem in the prior art. Furthermore, those skilled in the art will readily appreciate that the above description is only illustrative of specific embodiments and examples of the invention. The invention should therefore cover various modifications and variations made to the herein-described structure and operations of the invention, provided they fall within the scope of the invention as defined in the following appended claims.

1. A method of producing a white light with adjustable color temperature, comprising:
providing a blue light-emitting diode emitting a blue light which has a wavelength in a range from 400 nm to 500 nm;
preparing a phosphor powder emitting a phosphor light which has a wavelength in a range from 540 nm to 700 nm, wherein the phosphor light is mixed with the blue light of the blue light-emitting diode to produce a white light with a color temperature value above 6500 K; and
adding an orange light-emitting diode emitting a light which has a wavelength in a range from 540 nm to 600 nm, wherein the orange light-emitting diode is adjusted by a driving current for decreasing a color temperature value of said white light.

2. The method according to claim 1, wherein a luminescent layer of the blue light-emitting diode is made of a nitride semiconductor.

3. The method according to claim 1, wherein the phosphor powder is selected from a group consisting of Y₃Al₅O₁₂:Ce, Gd, CaS:Eu and SrGa₂S₄:Eu.

4. The method according to claim 1, wherein the phosphor powder is prepared by one of a solid reaction method and a chemical synthesizing method.

5. The method according to claim 4, wherein the chemical synthesizing method is a citrate gel method or a co-precipitation method.

6. The method according to claim 1, wherein a luminescent layer of the orange light-emitting diode is made of a nitride semiconductor or a phosphide semiconductor.

7. The method according to claim 1, wherein the color temperature value of the white light is adjusted in a range from 2000 K to 20000 K.

8. A method of producing a white light with adjustable color temperature, comprising:
providing a blue light-emitting diode emitting a blue light which has a wavelength in a range from 400 nm to 500 nm;
preparing a phosphor powder emitting a phosphor light which has a wavelength in a range from 540 nm to 700 nm, wherein the phosphor light is mixed with the blue light of the blue light-emitting diode to produce a white light with a color temperature value below 6500 K; and
adding a blue-green light-emitting diode emitting a light which has a wavelength in a range from 480 nm to 500 nm, wherein the blue-green light-emitting diode is adjusted by a driving current for increasing a color temperature value of said white light.

9. The method according to claim 8, wherein a luminescent layer of the blue light-emitting diode is made of a nitride semiconductor.

10. The method according to claim 8, wherein the phosphor powder is selected from a group consisting of Y₃Al₅O₁₂:Ce, Gd, CaS:Eu and SrGa₂S₄:Eu.

11. The method according to claim 8, wherein the phosphor powder is prepared by one of a solid reaction method and a chemical synthesizing method.

12. The method according to claim 11, wherein the chemical synthesizing method is a citrate gel method or a co-precipitation method.

13. The method according to claim 8, wherein a luminescent layer of the blue-green light-emitting diode is made of a nitride semiconductor or a phosphide semiconductor.

14. The method according to claim 8, wherein the color temperature value of the white light is adjusted in a range from 2000 K to 20000 K.

15. A white light apparatus with adjustable color temperature, comprising:
a blue light-emitting diode emitting a blue light;
a phosphor powder emitting a phosphor light, wherein the phosphor light is mixed with the blue light of the blue light-emitting diode to produce a white light with a high or a low color temperature value; and
a luminescent component emitting a light which has a wavelength in a range from 480 nm to 600 nm, wherein the luminescent component is controlled by a driving current for adjusting a color temperature value of said white light.

16. The white light apparatus according to claim 15, wherein a luminescent layer of the blue light-emitting diode is made of a nitride semiconductor.

17. The white light apparatus according to claim 15, wherein the blue light of the blue light-emitting diode has a wavelength in a range from 400 nm to 500 nm.

18. The white light apparatus according to claim 15, wherein the phosphor light of the phosphor powder has a wavelength in a range from 540 nm to 700 nm.

19. The white light apparatus according to claim 15, wherein the phosphor powder is one of A₃B₅O₁₂:Ce, Gd, CaS:Eu and SrGa₂S₄:Eu.

20. The white light apparatus according to claim 19, wherein the A element of the A₃B₅O₁₂:Ce phosphor powder is selected from a group consisting of Y, Tb, La, Gd, Pr and Sm, and the B element of the A₃B₅O₁₂:Ce phosphor powder is selected from a group consisting of Al, Ga, In and Fe for being activated with Ce.

21. The white light apparatus according to claim 15, wherein the color temperature value of the white light is adjusted in a range from 2000 K to 20000 K.
